(19) United States
(12) Patent Application Publication
(10) Pub. No.: US 2022/0100244 A1
(43) Pub. Date: Mar. 31, 2022

(54) MEMORY SYSTEM WITH CENTRALIZED POWER MANAGEMENT

(71) Applicant: Micron Technology, Inc., Boise, ID (US)

(72) Inventors: Marco Sforzin, Cernusco Sul Naviglio (MI) (IT); Paolo Amato, Treviglio (BG) (IT); Ferdinando Bedeschi, Biassono (MB) (IT); Daniele Balluchi, Cernusco Sul Naviglio (MI) (IT)

(21) Appl. No.: 17/033,583

(22) Filed: Sep. 25, 2020

(51) Int. Cl. G06F 1/26

(52) U.S. Cl. CPC G06F 1/26

(57) ABSTRACT

Methods, systems, and devices for a memory system with centralized power management are described. A memory system may include memory devices and a power management circuit. The memory devices may use one or more supply voltages during operation of the memory devices, which may include supply voltages received from an external device and high supply voltages generated within the memory system. The power management circuit may receive supply voltages from the external device and generate the supply voltages to the memory devices. The memory devices may exclude charge pump circuitry for generating supply voltages and may instead include pads for receiving the supply voltages from the power management circuit, in some examples. The memory system may include a controller that is configured to determine an amount of power to provide to the memory devices and transmit an indication of the amount of power to the power management circuit.

### BACKGROUND

The following relates generally to one or more memory systems and more specifically to heterogeneous memory system with centralized voltage management.

Memory devices are widely used to store information in various electronic devices such as computers, wireless communication devices, cameras, digital displays, and the like. Information is stored by programing memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read, or sense, the state of one or more memory cells within the memory device. To store information, a component may write, or program, one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), 3-dimensional cross-point memory (3D cross point), not-or (NOR) Flash-based memory, and not-and (NAND) Flash-based memory devices, and others. Memory devices may be volatile or non-volatile. Volatile memory cells (e.g., DRAM cells) may lose their programmed states over time unless they are periodically refreshed by an external power source. Non-volatile memory cells (e.g., NAND memory cells) may maintain their programmed states for extended periods of time even in the absence of an external power source.

### BRIEF DESCRIPTION OF THE DRAWINGS

FIG. 1 illustrates an example of a system that supports a memory system with centralized power management in accordance with examples as disclosed herein.

FIG. 2 illustrates an example of a system that supports a memory system with centralized power management in accordance with examples as disclosed herein.

FIG. 3 illustrates an example of a system that supports a memory system with centralized power management in accordance with examples as disclosed herein.

FIG. 4 illustrates an example of a system that supports a memory system with centralized power management in accordance with examples as disclosed herein.

FIG. 5 shows a block diagram of a system that supports a memory system with centralized power management in accordance with examples as disclosed herein.

FIG. 6 shows a flowchart illustrating a method or methods that support a system with centralized power management in accordance with examples as disclosed herein.

### DETAILED DESCRIPTION

Memory devices may receive several supply voltages from one or more power sources. Such supply voltages are used by the memory device to power its operations and generally have nominal voltage values that may be indicated in specification documents for the memory device. For example, a memory device may receive a VCC voltage, a VCCQ voltage, and/or other supply voltages that may be associated with (e.g., used for) operating the memory device. The nominal values of these supply voltages and the pads or pins used to receive these supply voltages at the memory device may be specified in a specification document for the memory device or in a standards document (e.g., a JEDEC standard), for example. A memory device may receive such supply voltages from one or more external devices, such as from a host device or an external voltage or power supply.

Some memory devices may use the supply voltages provided by external devices to internally generate additional supply voltages. For example, some non-volatile memory (NVM) devices may use the supply voltages provided by external devices to internally generate higher supply voltages or negative supply voltages that may be used to power operations on the memory devices. Thus, some memory devices may include on-die circuitry for generating such additional supply voltages based on (e.g., using) the supply voltages provided by external devices. For example, some memory devices may include internal (on-die) charge pump circuitry to produce the high voltages used for memory operations on these memory devices.

For example, some types of NVM memory, such as NAND memory, may receive VCC and VCCQ voltages from an external device and may internally generate one or more high supply voltages (e.g., VH1, VH2) based on the VCC and VCCQ voltages. These high supply voltages may be higher than the nominal VCC and VCCQ voltages and may be used, by the memory device, for executing operations on a memory array in the memory device. For example, a VCC voltage received from an external device may have a nominal value of 5.0 volts and a VH voltage generated by a NAND memory device may have a nominal value of 10.0 volts.

Some memory systems include multiple memory devices, each of which may include on-die circuitry for producing additional supply voltages. Some memory systems may be heterogeneous memory systems, meaning that they include memory devices having different types of memory. For example, a memory system may include one or more memory devices that each include a first type of memory (e.g., NAND memory) and one or more other memory devices that each include a second type of memory (e.g., emerging memory, self-selecting memory, 3D cross-point memory, or other types of memory). The two types of memory may use (e.g., be associated with) some of the same supply voltages for operation, but may use a different set of high supply voltages (or negative supply voltages). For example, the NAND memory devices and other memory devices may both use VCC and VCCQ supply voltages. The NAND memory devices may also use a first set of high voltages (e.g., VH1, VH2, VH3) that are higher than VCC and VCCQ, and the other memory devices may use a second set of high voltages (e.g., VK1, VK2, VK3) that are also higher than VCC and VCCQ but may be different than VH1, VH2, and VH3. In some cases, each of the memory devices may include circuitry for internally generating the set of high voltages used by the type of memory on the memory device.

As described herein, however, in some cases a memory device may receive one or more of the high supply voltages from a power management circuit rather than generating the high supply voltage(s) internally. For example, a power management circuit may receive VCC and VCCQ voltages from an external device and may generate VH1, VH2, VH3, VK1, VK2, and VK3 voltages. The power management circuit may provide the relevant supply voltages to each memory device based on the type of memory in the memory device; that is, the power management circuit may provide the VH1, VH2, and VH3 high voltages to NAND memory devices, and provide VK1, VK2, and VK3 high voltages to other memory devices.

Centralizing the power generation and distribution in this manner may have several benefits. For example, memory devices in the memory system may consume less power, area, or cost because they may exclude charge pump circuitry (or other circuitry that would otherwise be used for generating the high voltages) and may refrain from generating high (or negative) supply voltages internally. Instead, the memory devices may include a set of pads for receiving a corresponding set of high supply voltages from the power management circuit.

In addition, the power management circuit may include different circuitry for generating the high supply voltages than may otherwise be used in the memory devices. For example, rather than using charge pump circuitry, as is common in memory devices, the power management circuit may use a boost converter or inductor-based circuitry to generate the high supply voltages. Charge pump circuits are inductor-less circuits that include capacitors for raising or lowering voltages. A boost converter may increase (boost) a voltage using capacitors, inductors, or both. Inductor-based circuitry may include an inductor-based boost converter, or buck circuitry that uses an inductor to reduce a voltage. It may be difficult or impossible to fabricate inductors on memory devices, which may therefore rely on charge pump circuitry. In contrast, it may be possible to fabricate inductors within a power management circuit, providing different and possibly more efficient options for generating high (or negative) supply voltages.

Moreover, by centralizing power generation and distribution, the memory system may be able to adjust overall power distribution in the memory system based on, for example, current or expected power demand of various memory devices or groups of memory devices. For example, a memory system may include a controller that may determine an amount of power to distribute to various memory devices in the system based on actual or expected demand on the memory devices. The controller may transmit, to the power management circuit, an indication of the amount of power to distribute to the memory devices, and the power management circuit may generate and distribute the supply voltages accordingly. For example, the power management circuit may reduce or increase the voltage value of one or more of the high supply voltages (within a nominal voltage range) based on information received from the controller to provide additional power to memory devices experiencing high demand.

In some examples, one or more of the memory devices in the system may include on-die circuitry for measuring power consumption (e.g., current demand) on the die, and the memory device(s) may provide feedback to the controller indicating the power consumption at the memory device(s). The controller may receive such feedback from the memory device(s) in the system, and may determine the amount of power to distribute to the memory devices based on this feedback information. In some examples, a memory device may transmit a request for an amount of power to the controller, and the controller may use the request to determine the amount of power to distribute to the memory devices. Thus, using centralized power management may enable more efficient distribution of power to multiple memory devices, thereby increasing the power efficiency and performance of the overall system. Although the discussion herein focuses on high supply voltages—that is, supply voltages that are higher than the supply voltages received from an external device—such discussion also applies to negative supply voltages that may be generated based on supply voltages received from an external device.

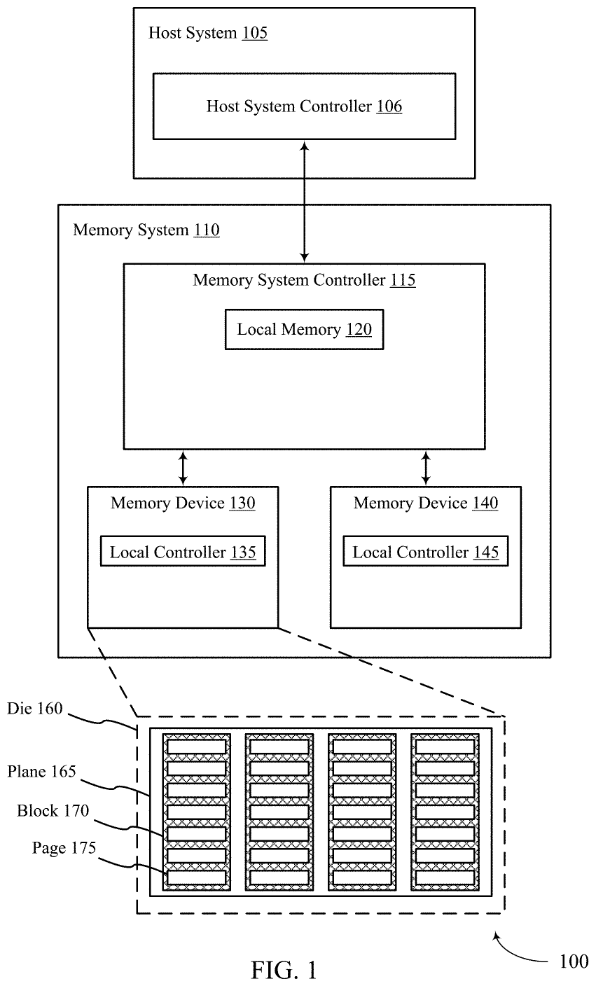

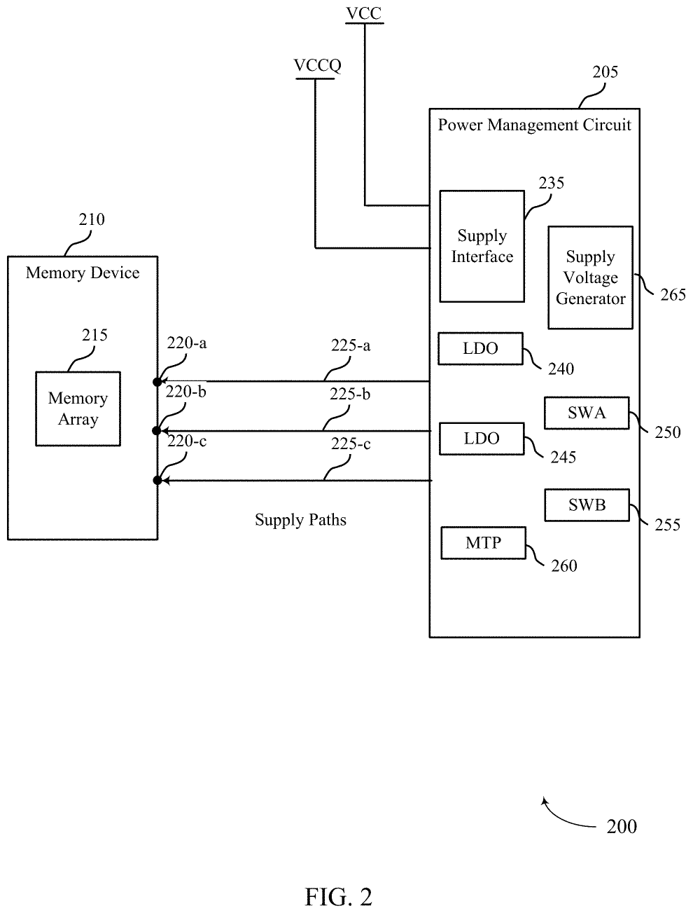

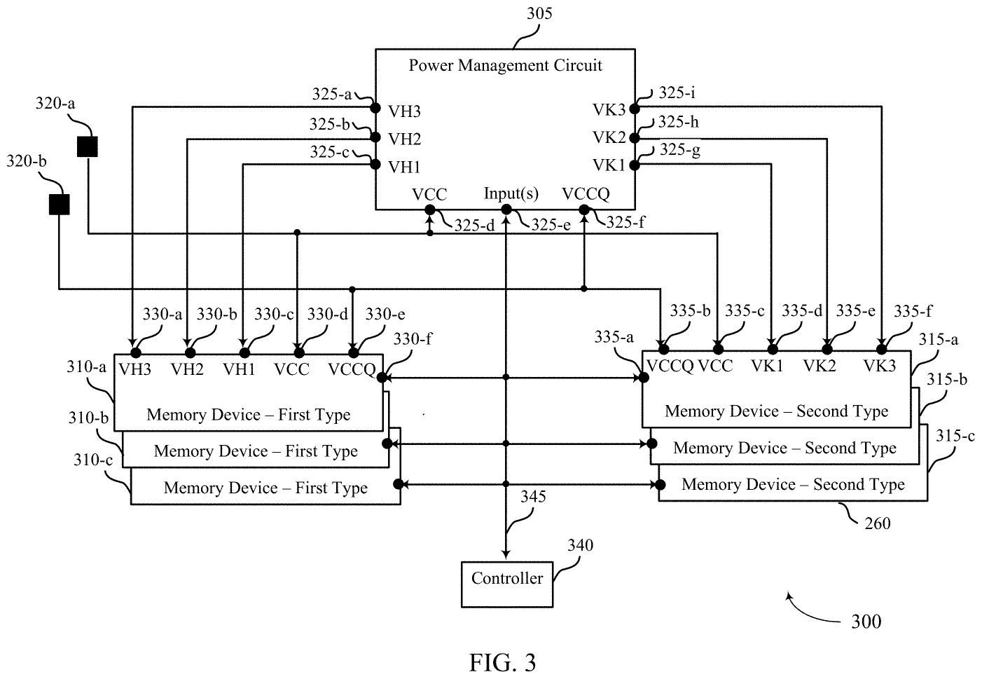

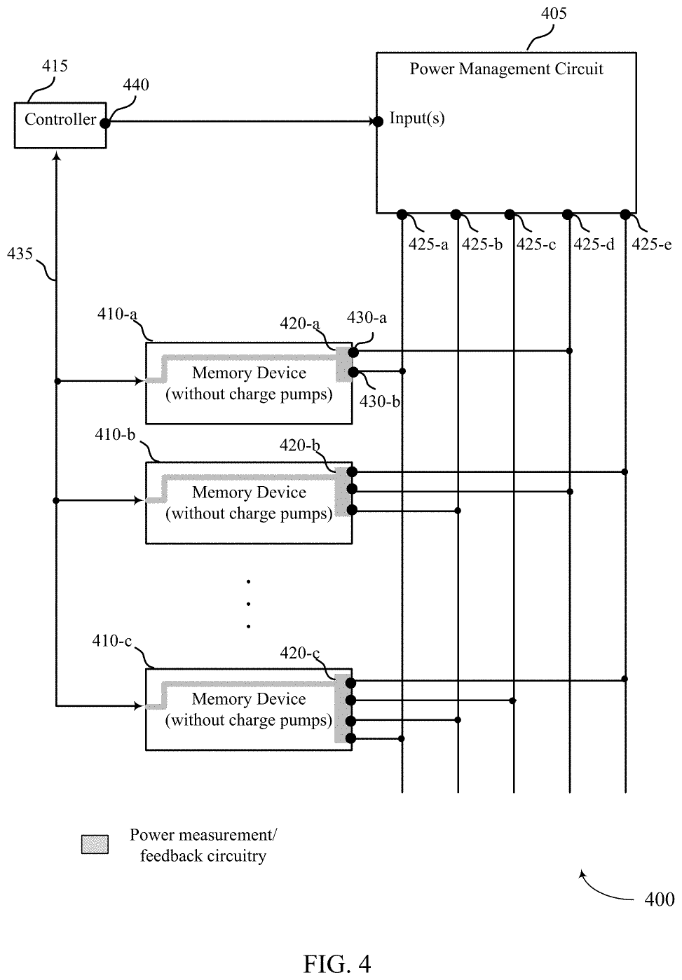

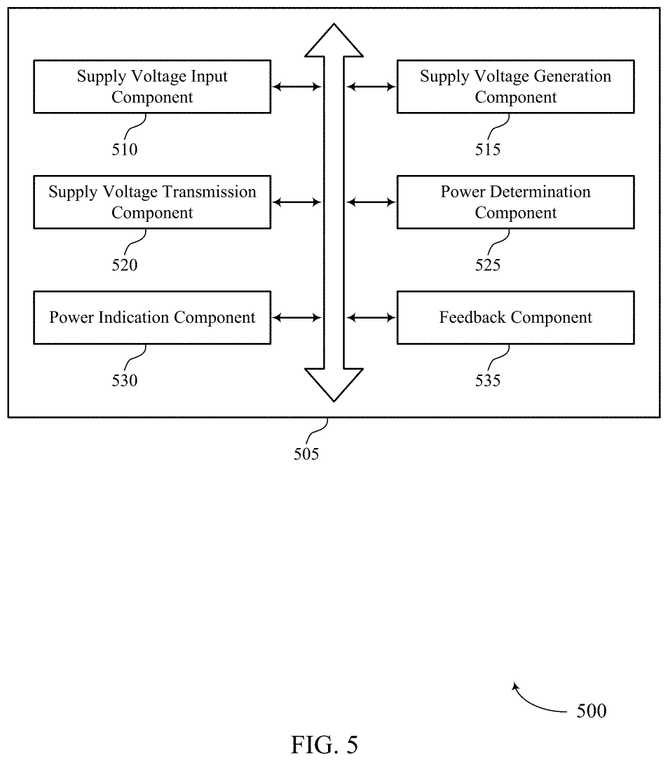

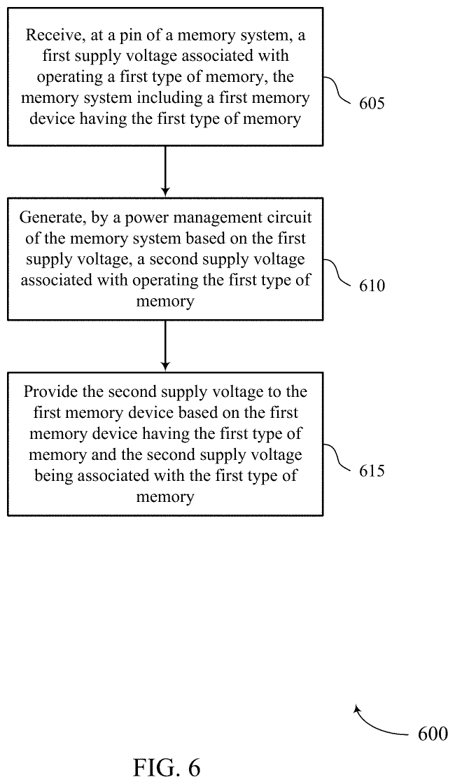

Features of the disclosure are initially described in the context of systems and devices as described with reference to FIGS. 1 and 2. Features of the disclosure are described in the context of systems as described with reference to FIGS. 3 and 4. These and other features of the disclosure are further illustrated by and described with reference to an apparatus diagram and a flowchart that relate to a memory system with centralized power management as described with reference to FIGS. 5 and 6.

FIG. 1 is an example of a system 100 that supports a memory system with centralized power management in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a control component configured to cause the host system 105 to perform various operations in accordance with examples as described herein. The host system 105 may include one or more devices, and in some cases may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., PCIe controller, SATA controller). The host system 105 may use the memory system 110, for example, to write data to the memory system 110 and read data from the memory system 110. Although one memory system 110 is shown in FIG. 1, it is to be understood that the host system 105 may be coupled with any quantity of memory systems 110.

The host system 105 may be coupled with the memory system 110 via at least one physical host interface. The host system 105 and the memory system 110 may in some cases be configured to communicate via a physical host interface using an associated protocol (e.g., to exchange or otherwise communicate control, address, data, and other signals between the memory system 110 and the host system 105). Examples of a physical host interface may include, but are not limited to, a serial advanced technology attachment (SATA) interface, a UFS interface, an eMMC interface, a peripheral component interconnect express (PCIe) interface, USB interface, Fiber Channel, Small Computer System Interface (SCSI), Serial Attached SCSI (SAS), Double Data Rate (DDR), a dual in-line memory module (DIMM) interface (e.g., DIMM socket interface that supports DDR), Open NAND Flash Interface (ONFI), Low Power Double Data Rate (LPDDR). In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 or memory device 140 included in the memory system 110, or via a respective physical host interface for each type of memory device 130 or memory device 140 included in the memory system 110.

Memory system 110 may include a memory system controller 115, a memory device 130, and a memory device 140. A memory device 130 may include one or more memory arrays of a first type of memory cells (e.g., a type of non-volatile memory cells), and a memory device 140 may include one or more memory arrays of a second type of memory cells (e.g., a type of volatile memory cells). Although one memory device 130 and one memory device 140 are shown in the example of FIG. 1, it is to be understood that memory system 110 may include any quantity of memory devices 130 and memory devices 140, and that, in some cases, memory system 110 may lack either a memory device 130 or a memory device 140.

The memory system controller 115 may be coupled with and communicate with the host system 105 (e.g., via the physical host interface), and may be an example of a control component configured to cause the memory system 110 to perform various operations in accordance with examples as described herein. The memory system controller 115 may also be coupled with and communicate with memory devices 130 or memory devices 140 to perform operations such as reading data, writing data, erasing data, or refreshing data at a memory device 130 or a memory device 140, and other such operations, which may generically be referred to as access operations. In some cases, the memory system controller 115 may receive commands from the host system 105 and communicate with one or more memory devices 130 or memory devices 140 to execute such commands (e.g., at memory arrays within the one or more memory devices 130 or memory devices 140). For example, the memory system controller 115 may receive commands or operations from the host system 105 and may convert the commands or operations into instructions or appropriate commands to achieve the desired access of the memory devices 130 or memory devices 140. And in some cases, the memory system controller 115 may exchange data with the host system 105 and with one or more memory devices 130 or memory devices 140 (e.g., in response to or otherwise in association with commands from the host system 105). For example, the memory system controller 115 may convert responses (e.g., data packets or other signals) associated with the memory devices 130 or memory devices 140 into corresponding signals for the host system 105.

The memory system controller 115 may be configured for other operations associated with the memory devices 130 or memory devices 140. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130 or memory devices 140.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally or alternatively, the local memory 120 may serve as a cache for the memory system controller 115. For example, data may be stored to the local memory 120 when read from or written to a memory device 130 or memory device 140, and may be available within the local memory 120 for subsequent retrieval for or manipulation (e.g., updating) by the host system 105 (e.g., with reduced latency relative to a memory device 130 or memory device 140) in accordance with a cache policy.

Although the example of memory system 110 in FIG. 1 has been illustrated as including the memory system controller 115, in some cases, a memory system 110 may not include a memory system controller 115. For example, the memory system 110 may additionally or alternatively rely upon an external controller (e.g., implemented by the host system 105) or one or more local controllers 135 or local controllers 145, which may be internal to memory devices 130 or memory devices 140, respectively, to perform the functions ascribed herein to the memory system controller 115. In general, one or more functions ascribed herein to the memory system controller 115 may in some cases instead be performed by the host system 105, a local controller 135, or a local controller 145, or any combination thereof.

A memory device 140 may include one or more arrays of volatile memory cells. For example, a memory device 140 may include random access memory (RAM) memory cells, such as dynamic RAM (DRAM) memory cells and synchronous DRAM (SDRAM) memory cells. In some examples, a memory device 140 may support random access operations (e.g., by the host system 105) with reduced latency relative to a memory device 130, or may offer one or more other performance differences relative to a memory device 130.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric RAM (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), and electrically erasable programmable ROM (EEPROM).

In some examples, a memory device 130 or a memory device 140 may include (e.g., on a same die or within a same package) a local controller 135 or a local controller 145, respectively, which may execute operations on one or more memory cells of the memory device 130 or the memory device 140. A local controller 135 or a local controller 145 may operate in conjunction with a memory system controller 115 or may perform one or more functions ascribed herein to the memory system controller 115. In some cases, a memory device 130 or a memory device 140 that includes a local controller 135 or a local controller 145 may be referred to as a managed memory device and may include a memory array and related circuitry combined with a local (e.g., on-die or in-package) controller (e.g., local controller 135 or local controller 145). An example of a managed memory device is a managed NAND (MNAND) device.

In some cases, a memory device 130 may be or include a NAND device (e.g., NAND flash device). A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may take place within different planes 165. For example, concurrent operations may be performed on memory cells within different blocks 170 so long as the different blocks 170 are in different planes 165. In some cases, performing concurrent operations in different planes 165 may be subject to one or more restrictions, such as identical operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may in some cases not be updated until the entire block 170 that includes the page 175 has been erased.

In some cases, a memory system controller 115, a local controller 135, or a local controller 145 may perform operations (e.g., as part of one or more media management algorithms) for a memory device 130 or a memory device 140, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for some or all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the number of blocks 170 that have been erased may be increased such that more blocks 170 are available to store subsequent data (e.g., data subsequently received from the host system 105).

The system 100 may include any quantity of non-transitory computer readable media that support a memory system with centralized power management. For example, the host system 105, the memory system controller 115, a memory device 130, or a memory device 140 may include or otherwise may access one or more non-transitory computer readable media storing instructions (e.g., firmware) for performing the functions ascribed herein to the host system 105, memory system controller 115, memory device 130, or memory device 140. For example, such instructions, when executed by the host system 105 (e.g., by the host system controller 106), by the memory system controller 115, by a memory device 130 (e.g., by a local controller 135), or by a memory device 140 (e.g., by a local controller 145), may cause the host system 105, memory system controller 115, memory device 130, or memory device 140 to perform one or more associated functions as described herein.

In some examples, host system 105 (or another device that is external to memory system 110) may provide one or more supply voltages to memory system 110, such as a VCC supply voltage, a VCCQ supply voltage, or another supply voltage. Memory system 110 may generate additional supply voltages, such as high supply voltages or negative supply voltages, based on the supply voltages received from host system 105. Memory system 110 may provide the generated supply voltages to one or more memory devices in memory system 110, such as to memory device 130, memory device 140, or both, via pads or pins.

In some examples, memory devices in memory system 110 may be a heterogeneous memory system that includes different types of memory devices. For example, memory device 130 may include NAND (Flash) memory cells and memory device 140 may include a different type of NVM cells. Memory system 110 may generate and provide different high supply voltages (or negative supply voltages) for the different types of memory. In some examples, one or more memory devices in memory system 110 may exclude circuitry for internally generating high supply voltages or negative supply voltages used by the memory devices, and may instead receive such high supply voltages from another component in memory system 110, such as from memory system controller 115 or from a power management circuit (not shown).

In some examples, memory system 110 may include a controller (e.g., memory system controller or another controller) that may determine an amount of power to provide to memory devices in memory system 110 and may transmit an indication of the amount of power to a power management circuit in memory system 110. The power management circuit may generate and distribute and amount of power to memory devices in memory system 110 based on the indication received from the controller.

In some examples, one or more memory devices in memory system 110 may include circuitry for measuring on-die power consumption of the memory device. The memory device may transmit feedback information regarding the on-die power consumption to a controller of memory system 110, such as to memory system controller 115, for example. The controller may determine the amount of power to provide to the memory devices based on the feedback information received from the memory devices.

FIG. 2 illustrates an example of a system 200 that supports a memory system with centralized power management. The system 200 may include a power management circuit 205, a memory device 210 that includes a memory array 215, and one or more supply paths 225 (e.g., supply path 225-a, 225-b, 225-c) between the power management circuit 205 and the memory device 210. The memory device 210 may be an example of a memory device 130, 140 as described with reference to FIG. 1. In the example of system 200, the supply paths 225 may be examples of conductive lines that couple the power management circuit 205 with the memory device 210 via corresponding pads 220 (e.g., pad 220-a, 220-b, 220-c).

Memory array 215 may include volatile memory cells, such as DRAM cells, or NVM memory cells, such as NAND (Flash) memory cells or another type of NVM cells. In some examples, system 200 may include multiple memory devices 210, which may include different types of memory arrays 215. For example, a first memory device 210 may include a first type of NVM cells and a second memory device (not shown) may include a second type of NVM cells.

The power management circuit 205 may include a supply interface 235, low-dropout regulators (LDO) 240, 245, power supplies (SWA, SWB) 250, 255 (e.g., switching regulators), and multi-time programmable memory (MTP) 260. The supply interface 235 may be operable to receive power (e.g., by receiving supply voltages such as VCC and VCCQ) to activate the power management circuit 205 and to be distributed to other components of a memory system (e.g., memory device 210) through the power management circuit 205. In some examples, power management circuit 205 may receive power from an external device, such as a host system, voltage supply, or another device.

The low-dropout regulators 240, 245 may be used for outputting power (e.g., DC power) to memory devices of the memory system, including memory device 210. In some cases, the low-dropout regulators 240, 245 may be used to regulate an output voltage, such as a supply voltage. The power supplies 250, 255 may be used for outputting power to memory devices of the memory system, including memory device 210. The power management circuit 205 may include any quantity of low-dropout regulators (e.g., one, two, three, four, five, six, seven, eight), or may include any quantity of power supplies (e.g., one, two, three, four, five, six, seven, eight), or any quantity of both.

The supply voltage generator 265 may be used to generate high supply voltages, negative supply voltages, or both based on (e.g., using) the supply voltages received from an external device (e.g., VCC and VCCQ, for example). Supply voltage generator 265 may include a charge pump, boost converter, inductor-based circuitry, DC-DC converter, or other types of voltage generation circuitry, or a combination thereof that may be used to generate the high supply voltages or negative supply voltages.

The multi-time programmable memory 260 may be any type of memory used by the power management circuit 205 for performing the functions described herein. In some cases, the multi-time programmable memory 260 may be an example of an electrically erasable programmable read-only memory (EEPROM) or other type of memory technology. The multi-time programmable memory 260 may be used for protecting circuits, improving a reliability of a power-on sequence or a power-off sequence, setting of output voltage(s), setting of output pull-down resistance(s), or other functions, or any combination thereof.

The supply paths 225 may be conductive paths that may include one or more power supply rails to enable the power management circuit 205 to distribute a supply voltage to memory device 210, for example.

In some examples, supply paths 225 may include conductive paths for providing, to memory device 210, high supply voltages or negative supply voltages that are generated by supply voltage generator 265 of power management circuit 205. In some examples, each supply voltage generated by power management circuit 205 may be provided to memory device 210 via a corresponding pad 220, for example.

In some examples, power management circuit 205 may be located on (e.g., fabricated on) a separate die from memory device 210. Fabricating power management circuit 205 on a separate die may provide benefits relative to the case of fabricating power management circuit 205 on the same die as memory device 210, such as reducing the standby current of memory device 210 and improving the power efficiency of system 200. In some examples, power management circuit 205 and memory device 210 may be packaged together on a single packaging substrate.

In some examples, power management circuit 205 may be coupled with a controller in system 200, or may be included within a controller of system 200. As described herein, a power management circuit 205 may receive, from the controller, an indication of an amount (e.g., a quantity) of power to provide to memory device 210. Power management circuit 205 may generate and distribute one or more high supply voltages or negative supply voltages to memory device(s) 210 based on the indication of the amount of power received from the controller. For example, power management circuit 205 may select a voltage value of the high supply voltage based on the indication of the amount of power and generate the high supply voltage based on the selected voltage value. For example, power management circuit 205 may determine whether to provide a high supply voltage to a particular memory device 210 based on the indication of the amount of power.

FIG. 3 illustrates an example of a system 300 that supports centralized power management in accordance with examples as disclosed herein. The system 300 may include power management circuit 305, a set of one or more first type of memory devices 310, and a set of one or more second type of memory devices 315. For example, the first type of memory devices 310 may be memory devices having a first type of memory, such as a type of NVM such as Flash-based (e.g., NAND) memory. For example, the second type of memory devices 315 may be memory devices having a second type of memory that is a different type of memory than the first type of memory, such as a different type of NVM (e.g., EM) or a type of volatile memory.

The system 300 may include a controller 340. Controller 340 may be an example of a memory system controller 115 or may represent other controller circuitry. In some examples, power management circuit 305 may be included in controller 340. In some examples, power management circuit 305 and/or controller 340 may each be located on (e.g., fabricated on) separate dice from memory devices 310, 315. In some examples, power management circuit 305 and controller 340 may be located on the same die or on separate dice. In some examples, power management circuit 305, controller 340, and memory devices 310, 315 may be packaged together on a single packaging substrate.

The system 300 may receive one or more supply voltages from an external device via one or more pins 320 of system 300. For example, system 300 may receive a VCC supply voltage using pin 320-a and may receive a VCCQ voltage using pin 320-b. The system 300 may provide such externally supplied supply voltages to power management circuit 305 via pads 325-d, 325-f respectively, of power management circuit 305. In some examples, system 300 or power management circuit 305 may provide such externally supplied supply voltages to one or more memory devices 310, 315 via corresponding pads (e.g., via pads 330-d, 330-e, 335-b, 335-c of memory devices 310, 315).

Power management circuit 305 may generate one or more additional supply voltages, such as high supply voltages or negative voltages, based on the received supply voltages. Power management circuit 305 may be configured to provide (e.g., transmit, distribute) one or more of the generated supply voltages to one or more memory devices 310, 315 via corresponding pads 330, 335 of the memory devices 310, 315.

For example, power management circuit 305 may be configured to receive a VCC supply voltage and VCCQ supply voltage and generate VH1, VH2, VH3 supply voltages associated with operating the first type of memory devices 310. Power management circuit 305 may provide the VH1, VH2, and VH3 supply voltages to one or more of the first type of memory devices 310 via corresponding pads 330 on each memory device 310. That is, each memory device 310 may receive a VH3 supply voltage via a first pad 330-a of the memory device 310, a VH2 supply voltage via a second pad 330-b of the memory device 310, and a VH1 supply voltage via a third pad 330-c of the memory device 310. In some cases, the voltage values for VH1, VH2, and VH3 may depend on the voltage values of VCC and VCCQ.

Similarly, power management circuit 305 may be configured to receive a VCC supply voltage and VCCQ supply voltage and generate VK1, VK2, VK3 supply voltages associated with operating the second type of memory devices 315. Power management circuit 305 may provide the VK1, VK2, and VK3 supply voltages to one or more of the second type of memory devices 315 via corresponding pads 335 on each memory device 315. That is, each memory device 315 may receive a VK1 supply voltage via a first pad 335-d of the memory device 315, a VK2 supply voltage via a second pad 335-e of the memory device 315, and a VK3 supply voltage via a third pad 335-f of the memory device 315. In some cases, the voltage values for VK1, VK2, and VK3 may depend on the voltage values of VCC and VCCQ.

The system 300 may include controller 340. Controller 340 may be configured to communicate with the first type of memory devices 310, the second type of memory devices 315, the power management circuit 305, or a combination thereof via one or more conductive paths 345.

Controller 340 may be configured to determine how much power (e.g., an amount of power) to provide to one or more of the first type of memory device 310, one or more of the second type of memory device 315, or both based on various criteria that the controller 340 may use to attempt to adjust the power distribution and performance of system 300 (e.g., optimize performance, in some cases). Controller 340 may provide an indication of the amount of power to provide to the one or more memory devices 310, 315 to power management circuit 305, and power management circuit 305 may then generate and distribute one or more high supply voltages based on this indication.

Controller 340 may determine the amount of power to provide to the one or more memory devices 310, 315 based on various criteria. For example, controller 340 may determine the amount of power based on feedback information received from one or more of memory devices 310, 315, where the feedback information includes a power parameter associated with one or more of the high supply voltages.

In some examples, the power parameter may indicate a power consumption measured at the one or more memory devices 310, 315. For example, one or more of the memory devices 310, 315 may include circuitry for measuring the power consumption (e.g., voltage, current) at a pad(s) of the memory device 310, 315 that may be used to receive a high supply voltage from power management circuit 305 (such as at pads 330-a, 330-b, 330-c, 335-d, 335-e, 335-f). Memory devices 310, 315 may transmit an indication(s) of the power consumption at such pads to controller 340 (e.g., via pads 330-f, 335-a of memory device 310, 315, respectively) as a power parameter within the feedback information. Controller 340 may determine the amount of power to provide to one or more of memory devices 310, 315 based on the received indication(s).

In some examples, one or more of memory devices 310, 315 may transmit an indication of a requested an amount of power to controller 340, where the requested amount of power may be determined by memory device 310, 315 based on, for example, the measured or expected power consumption at memory device 310, 315, a desired performance level at memory device 310, 315, an operation being performed by memory device 310, 315, a state of memory device 310,315, other factors, or a combination thereof. Controller 340 may determine the amount of power to provide to one or more of memory devices 310, 315 based on the indication(s) of the requested amount of power. That is, controller 340 may allocate the power in an overall power budget for system 300 among memory devices 310, 315 based on one or more requests for an amount of power received from memory devices 310, 315.

In some examples, controller 340 may determine a current or expected power demand of system 300 based on feedback information received from memory devices 310, 315, based on commands in a command queue of system 300 (such as memory access commands or other commands), based on other factors, or a combination thereof. Controller 340 may determine an amount of power to provide to the one or more memory devices 310, 315 based on the power demand.

In some examples, based on the commands in the command queue, or based on other, information regarding each command, controller 340 may determine the most convenient command execution sequence to adopt to reduce the overall execution time of the commands at a given an upper level of power consumption (e.g., a maximum power consumption). In some examples, controller 340 may temporarily suspend the execution of some operations, without compromising the quality of service of the system. Moreover, the controller 340 may decide to adopt selective standby or power-down states (or other low consumption power state) for some of (or all) the memory devices 310, 315. Controller 340 may determine the amount of power to supply to the one or more memory devices 310, 315 based on any combination of these factors.

FIG. 3 provides a non-limiting example of a memory system that may include the supply voltages and memory devices as shown. Other quantities or values of supply voltages and memory devices may be used without departing from the scope of the disclosure. For example, although FIG. 3 depicts two supply voltages (VCC and VCCQ) received from an external device, a memory system may receive a different quantity of supply voltages, and that such received supply voltages may differ from VCC and VCCQ supply voltages (in terms of voltage values, for example) depending on the memory system. Furthermore, power management circuit 305 may generate and distribute a different quantity or value of high supply voltages (or negative supply voltages) than those shown in FIG. 3. Additional details and examples of controller-based adjustments (e.g., optimization) of power generation and distribution are described with reference to FIG. 4.

FIG. 2 illustrates an example of a system 200 that supports centralized power management in accordance with examples as disclosed herein. The system 400 may be an example of or may include aspects of systems 110, 200, 300, for example. The system 400 may include a power management circuit 405, one or more memory devices 410, and a controller 415.

Power management circuit 405 may be configured to generate and distribute high supply voltages to memory devices 410 as described with reference to FIG. 3, such as via corresponding pads 425 of power management circuit 405. Each memory device 410 may receive one or more of the high supply voltages from power management circuit 405 via corresponding pads 430 of memory device 410.

In some examples, as shown in FIG. 4, one or more of memory devices 410 may exclude charge pumps (or other circuitry) that may be used to generate high supply voltages. In other examples, one or more of memory devices 410 may include such charge pumps or other circuitry, and may be configured to receive some high supply voltages from power management circuit 405 and generate other high supply voltages internally. In some examples, one or more of memory devices 410 may include charge pumps, but the charge pumps may be disabled or partially enabled.

Memory devices 410 may include on-die power measurement/feedback circuitry 420 for measuring the power consumption at one or more pads 430 of memory device 410, such as circuitry for measuring the voltage, current, or both at pads 430 of memory device 410. In some examples, circuitry 420 may also be used to convert the measured power consumption into a sequence of bits representing the measured power consumption at one or more of the pads 430. Memory device 410 may transmit this sequence of bits (e.g., as a power parameter) to controller 415 via one or more conductive paths 435 to provide an indication of the power consumption at memory device 410, for example. In some examples, each memory device 410 may contain specific blocks (e.g., circuitry 420) used to measure the power consumption of the memory device 410 itself, and may make available a binary pattern (or code) associated with (e.g., representing) the level of power consumption in feedback information transmitted to controller 415.

Controller 415 may be configured to receive the indication(s) of the power consumption from one or more memory devices 410, such as in a power parameter as described with reference to FIG. 3. Controller 415 may determine, based on receiving the indication(s) of the power consumption from one or more memory devices 410, an amount of power to provide to one or more memory devices 410. Controller 415 may transmit an indication of the amount of power to power management circuit 405. Power management circuit 405 may generate and distribute one or more high supply voltages to one or more memory devices 410 based on the indication received from controller 415.

For example, power management circuit 405 may generate a high supply whose voltage value is based on the indication received from the controller 415. That is, power management circuit 405 may increase or decrease the voltage value of the high supply voltage relative to its nominal value based on the indication of the amount of power received from controller 415.

In some examples, power management circuit 405 may transmit, to a memory device 410, an indication of an amount of power that the memory device 410 is allowed to consume. Based on the received indication of the amount of power that the memory device 410 is allowed to consume, the memory device 410 may suspend its operation (such as by entering a stand-by mode or a low-power mode) or operate at a reduced performance level.

In some examples, controller 415 may be configured to sample the state of the power consumption at one or more of memory devices 410, such as by transmitting a request for power consumption information to one or more of memory devices 410 and receiving, in response, an indication of the power consumption (e.g., in feedback information including a power parameter) from one or more of memory devices 410. Controller 415 may allocate a residual power budget (e.g., a power budget remaining after considering (e.g., subtracting) the power consumption reported by memory devices 410) to executing one or more commands in a command queue, for example.

In some examples, power management circuit 405 may determine a total amount of power consumed by memory devices 410, such as based on feedback information received from memory devices 410. Power management circuit 405 may transmit, to controller 415, an indication of the total amount of power consumed by memory devices 410. Controller 415 may schedule commands for memory devices 410 based on the indication of the total amount of power received from power management circuit 405.

In some examples, controller 415 may determine, based on receiving feedback information from one or more memory devices 410, an operation (or group of operations) to execute on one or more memory devices 410. For example, controller 415 may select one or more commands from a command queue to be executed on one or more memory devices 410, where each command may specify an operation such as a read operation, write operation, erase operation, or another operation. Controller 415 may select the one or more commands based on a priority associated with the commands, or based on a power consumption associated with executing the commands, for example. Controller 415 may then cause the selected commands to be executed on the one or more memory devices 410.

In some examples, controller 415 may determine a priority of memory access operations to be performed on memory devices 410 (e.g., as specified by commands in a command queue) or determine a sequence of commands in a command queue, and may determine the amount of power to provide to the memory device(s) 410 based on some or all of these factors.

FIG. 5 shows a block diagram 500 of a system 505 that supports a memory system with centralized power management in accordance with examples as disclosed herein. The system 505 may be an example of aspects of a memory system as described with reference to FIGS. 1 through 4. The system 505 may include a supply voltage input component 510, a supply voltage generation component 515, a supply voltage transmission component 520, a power determination component 525, a power indication component 530, and a feedback component 535. Each of these modules may communicate, directly or indirectly, with one another (e.g., via one or more buses).

The supply voltage input component 510 may receive, at a pin of the memory system, a first supply voltage associated with operating a first type of memory, the memory system including a first memory device having the first type of memory. The supply voltage generation component 515 may generate, using a power management circuit of the memory system and based on the first supply voltage, a second supply voltage associated with operating the first type of memory. In some examples, generating the second supply voltage based on the first supply voltage includes generating the second supply voltage using a charge pump, a boost converter, inductor-based circuitry, or a combination thereof.

In some examples, the supply voltage generation component 515 may generate, using the power management circuit and based on the first supply voltage, a third supply voltage associated with operating the second type of memory. In some cases, the second supply voltage, the third supply voltage, or both are higher voltages than the first supply voltage. In some cases, the second supply voltage, the third supply voltage, or both are negative voltages. In some cases, the first supply voltage, the second supply voltage, and the third supply voltage are different voltages. In some cases, the first type of memory is a first type of non-volatile memory and the second type of memory is a second type of non-volatile memory.

The supply voltage transmission component 520 may provide the second supply voltage to the first memory device based on the first memory device having the first type of memory and the second supply voltage being associated with the first type of memory. In some examples, the supply voltage transmission component 520 may provide, by the power management circuit, the third supply voltage to the second memory device. In some examples, the supply voltage transmission component 520 may provide the first supply voltage to the first memory device, to the second memory device, or to both the first memory device and the second memory device.

The power determination component 525 may determine, using a controller of the memory system, an amount of power to provide to the first memory device. In some examples, the power determination component 525 may determine, using the controller, a power demand associated with operating a set of memory devices in the memory system, the set of memory devices including the first memory device. In some examples, determining the amount of power to provide to the first memory device includes determining a priority of memory access operations to be performed on a set of memory devices of the memory system, the set of memory devices including the first memory device, or determining a sequence of commands in a command queue of the memory system, or a combination thereof.

The power indication component 530 may transmit, by the controller to the power management circuit, an indication of the amount of power, where the second supply voltage provided to the first memory device is based on the indication of the amount of power.

The feedback component 535 may receive, by the controller from the first memory device, feedback information indicating a power parameter associated with the second supply voltage, where determining the amount of power to provide to the first memory device is based on receiving the feedback information. In some examples, the feedback component 535 may receive, using the controller and from a set of memory devices on the memory system, the set of memory devices including the first memory device, feedback information indicating respective power parameters associated with the second supply voltage for each memory device of the set of memory devices, where determining the amount of power to provide to the first memory device is based on receiving the feedback information from the set of memory devices. In some examples the feedback component 535 may receive, from the first memory device, an indication of a requested amount of power, where determining the amount of power to provide to the first memory device includes determining the amount of power based on the power demand and on the indication of the requested amount of power.

FIG. 6 shows a flowchart illustrating a method or methods 600 that supports a memory system with centralized power management in accordance with examples as disclosed herein. The operations of method 600 may be implemented by a system or its components as described herein. For example, the operations of method 600 may be performed by a system as described with reference to FIG. 5. In some examples, a system may execute a set of instructions to control the functional elements of the system to perform the described functions. Additionally or alternatively, a system may perform aspects of the described functions using special-purpose hardware.

At 605, a first supply voltage associated with operating a first type of memory may be received at a pin of the memory system, the memory system including a first memory device having the first type of memory. The operations of 605 may be performed according to the methods described herein. In some examples, aspects of the operations of 605 may be performed by a supply voltage input component as described with reference to FIG. 5.

At 610, a second supply voltage associated with operating the first type of memory may be generated using a power management circuit of the memory system based on the first supply voltage. The operations of 610 may be performed according to the methods described herein. In some examples, aspects of the operations of 610 may be performed by a supply voltage generation component as described with reference to FIG. 5.

At 615, the second supply voltage may be provided to the first memory device based on the first memory device having the first type of memory and the second supply voltage being associated with the first type of memory. The operations of 615 may be performed according to the methods described herein. In some examples, aspects of the operations of 615 may be performed by a supply voltage transmission component as described with reference to FIG. 5.

In some examples, an apparatus as described herein may perform a method or methods, such as the method 600. The apparatus may include features, means, or instructions (e.g., a non-transitory computer-readable medium storing instructions executable by a processor) for receiving, at a pin of the memory system, a first supply voltage associated with operating a first type of memory, the memory system including a first memory device having the first type of memory, generating, by a power management circuit of the memory system based on the first supply voltage, a second supply voltage associated with operating the first type of memory, and providing the second supply voltage to the first memory device based on the first memory device having the first type of memory and the second supply voltage being associated with the first type of memory.

Some examples of the method 600 and the apparatus described herein may further include operations, features, means, or instructions for determining, by a controller of the memory system, an amount of power to provide to the first memory device, and transmitting, by the controller to the power management circuit, an indication of the amount of power, where the second supply voltage provided to the first memory device may be based on the indication of the amount of power.

Some examples of the method 600 and the apparatus described herein may further include operations, features, means, or instructions for receiving, by the controller from the first memory device, feedback information indicating a power parameter associated with the second supply voltage, where determining the amount of power to provide to the first memory device may be based on receiving the feedback information.

Some examples of the method 600 and the apparatus described herein may further include operations, features, means, or instructions for receiving, by the controller from a set of memory devices on the memory system, the set of memory devices including the first memory device, feedback information indicating respective power parameters associated with the second supply voltage for each memory device of the set of memory devices, where determining the amount of power to provide to the first memory device may be based on receiving the feedback information from the set of memory devices.

Some examples of the method 600 and the apparatus described herein may further include operations, features, means, or instructions for determining, by the controller, a power demand associated with operating a set of memory devices in the memory system, the set of memory devices including the first memory device, and receiving, by the controller from the first memory device, an indication of a requested amount of power, where determining the amount of power to provide to the first memory device includes determining the amount of power based on the power demand and on the indication of the requested amount of power.

In some examples of the method 600 and the apparatus described herein, determining the amount of power to provide to the first memory device may include operations, features, means, or instructions for determining a priority of memory access operations to be performed on a set of memory devices of the memory system, the set of memory devices including the first memory device, or determining a sequence of commands in a command queue of the memory system, or a combination thereof.

In some examples of the method 600 and the apparatus described herein, the memory system may include operations, features, means, or instructions for generating, by the power management circuit based on the first supply voltage, a third supply voltage associated with operating the second type of memory, and providing, by the power management circuit, the third supply voltage to the second memory device.

In some examples of the method 600 and the apparatus described herein, the second supply voltage, the third supply voltage, or both may be higher voltages than the first supply voltage. In some examples of the method 600 and the apparatus described herein, the second supply voltage, the third supply voltage, or both may be negative voltages. In some examples of the method 600 and the apparatus described herein, the first supply voltage, the second supply voltage, and the third supply voltage may be different voltages.

Some examples of the method 600 and the apparatus described herein may further include operations, features, means, or instructions for providing the first supply voltage to the first memory device, to the second memory device, or to both the first memory device and the second memory device.

In some examples of the method 600 and the apparatus described herein, the first type of memory may be a first type of non-volatile memory and the second type of memory may be a second type of non-volatile memory.

In some examples of the method 600 and the apparatus described herein, generating the second supply voltage based on the first supply voltage may include operations, features, means, or instructions for generating the second supply voltage using a charge pump, a boost converter, inductor-based circuitry, or a combination thereof.

It should be noted that the methods described above describe possible implementations, and that the operations and the steps may be rearranged or otherwise modified and that other implementations are possible. Further, portions from two or more of the methods may be combined.

An apparatus is described. The apparatus may include a first memory device including a first type of memory, a first pin configured to receive a first supply voltage associated with operating the first type of memory, and a power management circuit coupled with the first pin and with the first memory device, the power management circuit configured to receive the first supply voltage, generate, based on the first supply voltage, a second supply voltage associated with operating the first type of memory, and provide the second supply voltage to the first memory device.

In some examples, the power management circuit includes a charge pump, a boost converter, inductor-based circuitry, or a combination thereof for generating the second supply voltage. In some examples, the first memory device excludes circuitry for generating supply voltages.

In some examples, a second memory device including a second type of memory, the second memory device coupled with the power management circuit, where the first supply voltage may be associated with operating the second type of memory, and where the power management circuit may be further configured to generate, based on the first supply voltage, a third supply voltage associated with operating the second type of memory and provide the third supply voltage to the second memory device.

In some examples, the second supply voltage, the third supply voltage, or both may be negative voltages or may be higher voltages than the first supply voltage.

Some examples of the apparatus may include a controller coupled with the first memory device and with the power management circuit, the controller configured to determine an amount of power to provide to the first memory device and transmit, to the power management circuit, an indication of the amount of power to provide to the first memory device, wherein the second supply voltage is based at least in part on receiving the indication of the amount of power.

In some examples, the power management circuit may be included in the controller.

Some examples may further include receiving, from a set of memory devices of the apparatus, the set of memory devices including the first memory device, feedback information indicating a respective power consumption at each of the set of memory devices, and where the controller may be configured to determine the amount of power to provide to the first memory device based on the feedback information.

An apparatus is described. The apparatus may include a non-volatile memory array having a first type and including a power distribution network for distributing a set of supply voltages to memory cells of the non-volatile memory array and a set of pads coupled with the power distribution network and configured to receive the set of supply voltages.

In some examples, the apparatus excludes circuitry for generating the set of supply voltages.

In some examples, the set of supply voltages includes a Vcc supply voltage and a high supply voltage that may be a higher voltage than the Vcc supply voltage.

Some examples of the apparatus may include one or more sensors for determining a power consumption associated with the apparatus, and a first pad for transmitting an indication of the power consumption to an external device.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method performed by a memory system, the method comprising:
receiving, at a pin of the memory system, a first supply voltage associated with operating a first type of memory, the memory system comprising a first memory device having the first type of memory;
generating, by a power management circuit of the memory system based at least in part on the first supply voltage, a second supply voltage associated with operating the first type of memory; and
providing the second supply voltage to the first memory device based at least in part on the first memory device having the first type of memory and the second supply voltage being associated with the first type of memory.

2. The method of claim 1, further comprising:
determining, by a controller of the memory system, an amount of power to provide to the first memory device; and
transmitting, by the controller to the power management circuit, an indication of the amount of power, wherein the second supply voltage provided to the first memory device is based at least in part on the indication of the amount of power.

3. The method of claim 2, further comprising:
receiving, by the controller from the first memory device, feedback information indicating a power parameter associated with the second supply voltage, wherein determining the amount of power to provide to the first memory device is based at least in part on receiving the feedback information.

4. The method of claim 2, further comprising:
receiving, by the controller from a plurality of memory devices on the memory system, the plurality of memory devices including the first memory device, feedback information indicating respective power parameters associated with the second supply voltage for each memory device of the plurality of memory devices, wherein determining the amount of power to provide to the first memory device is based at least in part on receiving the feedback information from the plurality of memory devices.

5. The method of claim 2, further comprising:
determining, by the controller, a power demand associated with operating a plurality of memory devices in the memory system, the plurality of memory devices including the first memory device; and
receiving, by the controller from the first memory device, an indication of a requested amount of power, wherein determining the amount of power to provide to the first memory device comprises determining the amount of power based at least in part on the power demand and on the indication of the requested amount of power.

6. The method of claim 2, wherein:
determining the amount of power to provide to the first memory device comprises determining a priority of memory access operations to be performed on a plurality of memory devices of the memory system, the plurality of memory devices including the first memory device, or determining a sequence of commands in a command queue of the memory system, or a combination thereof.

7. The method of claim 1, wherein the memory system comprises a second memory device having a second type of memory different than the first type of memory, the first supply voltage further associated with operating the second type of memory, the method further comprising:
generating, by the power management circuit based at least in part on the first supply voltage, a third supply voltage associated with operating the second type of memory; and
providing, by the power management circuit, the third supply voltage to the second memory device.

8. The method of claim 7, wherein the second supply voltage, the third supply voltage, or both are higher voltages than the first supply voltage.

9. The method of claim 7, wherein the second supply voltage, the third supply voltage, or both are negative voltages.

10. The method of claim 7, wherein the first supply voltage, the second supply voltage, and the third supply voltage are different voltages.

11. The method of claim 7, further comprising:
providing the first supply voltage to the first memory device, to the second memory device, or to both the first memory device and the second memory device.

12. The method of claim 7, wherein the first type of memory is a first type of non-volatile memory and the second type of memory is a second type of non-volatile memory.

13. The method of claim 1, wherein:
generating the second supply voltage based at least in part on the first supply voltage comprises generating the second supply voltage using a charge pump, a boost converter, an inductor, or a combination thereof.

14. An apparatus, comprising:
a first memory device comprising a first type of memory;
a first pin configured to receive a first supply voltage associated with operating the first type of memory; and
a power management circuit coupled with the first pin and with the first memory device, the power management circuit configured to:
receive the first supply voltage;
generate, based on the first supply voltage, a second supply voltage associated with operating the first type of memory; and
provide the second supply voltage to the first memory device.

15. The apparatus of claim 14, wherein the power management circuit comprises a charge pump, a boost converter, inductor-based circuitry, or a combination thereof for generating the second supply voltage.

16. The apparatus of claim 14, wherein the first memory device excludes circuitry for generating supply voltages.

17. The apparatus of claim 14, wherein:
a second memory device comprising a second type of memory, the second memory device coupled with the power management circuit, wherein the first supply voltage is associated with operating the second type of memory;
wherein the power management circuit is further configured to:
generate, based on the first supply voltage, a third supply voltage associated with operating the second type of memory; and
provide the third supply voltage to the second memory device.

18. The apparatus of claim 17, wherein the second supply voltage, the third supply voltage, or both are negative voltages or are higher voltages than the first supply voltage.

19. The apparatus of claim 14, further comprising:
a controller coupled with the first memory device and with the power management circuit, the controller configured to:
determine an amount of power to provide to the first memory device; and
transmit, to the power management circuit, an indication of the amount of power to provide to the first memory device, wherein the second supply voltage is based at least in part on receiving the indication of the amount of power.

20. The apparatus of claim 19, wherein the power management circuit is included in the controller.

21. The apparatus of claim 19, wherein the controller is configured to:
receive, from a plurality of memory devices of the apparatus, the plurality of memory devices including the first memory device, feedback information indicating a respective power consumption at each of the plurality of memory devices,
wherein the controller is configured to determine the amount of power to provide to the first memory device based at least in part on the feedback information.

22. An apparatus, comprising:
a non-volatile memory array having a first type of memory and comprising a power distribution network for distributing a plurality of supply voltages to memory cells of the non-volatile memory array; and
a plurality of pads coupled with the power distribution network and configured to receive the plurality of supply voltages.

23. The apparatus of claim 22, wherein the apparatus excludes circuitry for generating the plurality of supply voltages.

24. The apparatus of claim 22, wherein the plurality of supply voltages comprises a Vcc supply voltage and a high supply voltage that is a higher voltage than the Vcc supply voltage.

25. The apparatus of claim 22, further comprising:
one or more sensors for determining a power consumption associated with the apparatus; and
a first pad for transmitting an indication of the power consumption to an external device.
